(19) United States
(12) Patent Application Publication
(10) Pub. No.: US 2009/0003081 A1
(43) Pub. Date: Jan. 1, 2009

(54) Non-volatile memory and method of manufacturing same

(75) Inventors: Kenichi Hidaka, Kanagawa (JP); Noriaki Kodama, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kanagawa (JP)

(21) Appl. No.: 12/213,665

(22) Filed: Jun. 23, 2008

(30) Foreign Application Priority Data
Jun. 27, 2007 (JP) 2007-169017

(51) Int. Cl. G11C 11/34; H01L 27/115; H01L 21/8247

(52) U.S. Cl. 365/185.27; 257/316; 438/258; 257/E27.103; 257/E21.691

(57) ABSTRACT

The number of process steps for manufacturing a non-volatile memory is reduced while the performance of the non-volatile memory is improved. The non-volatile memory has a memory cell in which first, second and third P-type diffusion regions are formed in an N-type well, a select gate is formed via a select-gate insulating film over a channel between the first and second P-type diffusion regions, and a floating gate is formed via a floating-gate insulating film over a channel between the second and third P-type diffusion regions. The non-volatile memory has a peripheral circuit in which fourth and fifth P-type diffusion regions are formed in an N-type well, and a peripheral-circuit gate is formed via a peripheral-circuit gate insulating film over a channel between the fourth and fifth P-type diffusion regions. The film thickness of the floating-gate insulating film is greater than that of the select-gate insulating film and peripheral-circuit gate insulating film.

### FIELD OF THE INVENTION

This application is based upon and claims the benefit of the priority of Japanese patent application No. 2007-169017 filed on Jun. 27, 2007, the disclosure of which is incorporated herein in its entirety by reference thereto.

This invention relates to a single-layer-gate non-volatile memory and to a method of manufacturing the memory.

### BACKGROUND

A single-layer-gate non-volatile memory involving few or no additional process steps has recently come into use as a storage element for information set internally of a logic LSI chip. In a data cell 150 of a single-layer-gate non-volatile memory, as illustrated in FIG. 4 (see also Patent Documents 1 and 2), a first P-type diffusion region 118, a second P-type diffusion region 120 and a third P-type diffusion region 122 are formed in an N-type well 116, a select gate (control gate) 124 is formed over the channel between the first P-type diffusion region 118 and second P-type diffusion region 120 via a select-gate oxide film (control-gate oxide film) 134, and a P-type floating gate 166 is formed over the channel between the second P-type diffusion region 120 and third P-type diffusion region 122 via a floating-gate oxide film 132. In comparison with a stacked (two-layer) non-volatile memory in which a floating gate and a select gate are stacked over a channel between source/drain diffusion regions, this single-layer-gate non-volatile memory is advantageous in that it involves fewer process steps and lower manufacturing cost.

A method of manufacturing a conventional single-layer-gate non-volatile memory is as follows: First, the N-type well 116 is formed in a P-type substrate 130 (see FIG. 5A). Next, the first P-type diffusion region 118, second P-type diffusion region 120 and third P-type diffusion region 122 are formed in the N-type well 116 (see FIG. 5B). Next, the floating-gate oxide film 132 and select-gate oxide film 134 are formed in the N-type well 116 (see FIG. 5C). Next, the select gate 124 is formed over the select-gate oxide film 134 between the first P-type diffusion region 118 and the second P-type diffusion region 120, and the N-type well 116 and select gate 124 are isolated by the select-gate oxide film 134 (see FIG. 5D). Next, the P-type floating gate 166, which comprises P-type single-layer polysilicon, is formed over the floating-gate oxide film 132 between the second P-type diffusion region 120 and third P-type diffusion region 122, and the P-type floating gate 166 and N-type well 116 are isolated by the floating-gate oxide film 132 (see FIG. 5E).
[Patent Document 1] Japanese Patent Kokai Publication, No. P2003-168747A
[Patent Document 2] Japanese Patent Kokai Publication No. P2004-253685A

### SUMMARY OF THE DISCLOSURE

The entire disclosure of the above mentioned documents [Patent Docs. 1 and 2] are incorporated herein by reference thereto.

In order to improve the performance of a field-effect transistor, it is necessary that the gate insulating film interposed between the channel and gate electrodes be made thin. On the other hand, if the gate insulating film is thinned, the charge holding characteristic of the non-volatile memory deteriorates. In a non-volatile memory, therefore, it is desirable to form both a thick gate insulating film for the memory-cell region and a thin gate oxide film for the region of a peripheral circuit that includes a logic circuit.

However, the conventional single-layer-gate non-volatile memory involves certain problems. First, besides a process for forming a thin gate oxide film of the peripheral-circuit region, an additional process for forming a thick gate oxide film in the memory-cell region is required. Second, thinning of microfabrication has centered on the peripheral-circuit region that includes the logic circuit, and the device characteristics of the transistors in the memory-cell region and peripheral-circuit region differ from one another. Consequently, the impurity concentration of the well in the peripheral-circuit region tends to be higher than that of the well in the memory-cell region. Besides an ion injection process for forming the well of the peripheral-circuit region, an additional ion injection process for forming the N-type well in the memory-cell region becomes necessary. Third, since the film thickness of the select-gate oxide film in the memory-cell region is great just as is the film thickness of the floating-gate insulating film, the ON current of the memory cell is small.

Accordingly, it is an object of the present invention to reduce the number of process steps for manufacturing a non-volatile memory while improving the performance of the non-volatile memory.

According to a first aspect of the present invention, there is provided a non-volatile memory in which, in a memory cell, first, second and third diffusion regions are formed in a well, a select gate is formed via a select-gate insulating film over a channel between the first and second diffusion regions, and a floating gate is formed via a floating-gate insulating film over a channel between the second and third diffusion regions; wherein the floating-gate insulating film has a film thickness greater than that of the select-gate insulating film.

Preferably, in the non-volatile memory of the present invention, in a peripheral circuit disposed peripheral to the memory cell, fourth and fifth diffusion regions are formed in a well, a peripheral-circuit gate is formed via a peripheral-circuit gate insulating film over a channel between the fourth and fifth diffusion regions, and the wells of the memory cell and peripheral circuit have identical impurity concentrations.

Preferably, in the non-volatile memory of the present invention, the film thickness of the select-gate insulating film is equal to that of the peripheral-circuit gate insulating film.

According to a second aspect of the present invention, there is provided a method of manufacturing a non-volatile memory comprising: forming a through-insulating film, which is for well formation, on a substrate; forming wells in the substrate by ion injection; removing the through-insulating film at least in areas other than an area in which a memory transistor will be formed in the memory cell; and forming an insulating film, which is thinner than the through-insulating film, at least on the well that is in an area in which a select transistor will be formed in the memory cell.

Preferably, in the method of manufacturing the non-volatile memory according to the present invention, when the wells are formed, the wells of the memory cell and peripheral circuit are formed simultaneously.

Preferably, in the method of manufacturing the non-volatile memory, when the thinner insulating film is formed, an insulating film thinner than the through-insulating film is formed also on the well of the peripheral circuit.

According to a third aspect of the present invention, there is provided a method of operating a non-volatile memory. The method comprising:

providing a non-volatile memory comprising:

in a memory cell, first, second and third diffusion regions formed in a well;

a select gate formed via a select-gate insulating film over a channel between said first and second diffusion regions; and

a floating gate formed via a floating-gate insulating film over a channel between said second and third diffusion regions;

wherein the floating-gate insulating film has a film thickness greater than that of the select-gate insulating film.

Then a first voltage (e.g., 5V) is applied across from the first diffusion region and the well to the select gate, the third diffusion region being held at a second voltage (e.g., 0V) that is same as the select gate; thereby performing writing (e.g., “1”) in the memory cell.

Reading may be performed by applying:

a third voltage (e.g., 2V) lower than the first voltage to the well, and the first diffusion region; a fourth voltage (e.g., 1V) lower than the third voltage to the third diffusion region (e.g., 1V); and a fifth voltage (e.g., 0V) lower than the fourth voltage to the select gate.

The meritorious effects are achieved in accordance with the present invention, i.e., the select-gate insulating film is made thinner than the floating-gate insulating film without increasing the number of process steps. As a result, ON current is higher and memory operating speed improved in comparison with a conventional single-layer gate poly non-volatile memory in which both gate insulating films are thick. Further, by utilizing the through-insulating film for well formation at the floating-gate insulating film, it is unnecessary to add on a step of forming a thick floating-gate insulating film.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

FIG. 1 is a partial sectional view schematically illustrating the structure of a non-volatile memory according to a first example of the present invention;

FIGS. 2A to 2D are first process sectional views schematically illustrating a method of manufacturing a non-volatile memory according to the first example;

FIGS. 3A to 3C are second process sectional views schematically illustrating a method of manufacturing a non-volatile memory according to the first example;

FIG. 4 is a partial sectional view schematically illustrating the structure of a non-volatile memory according to the prior art; and

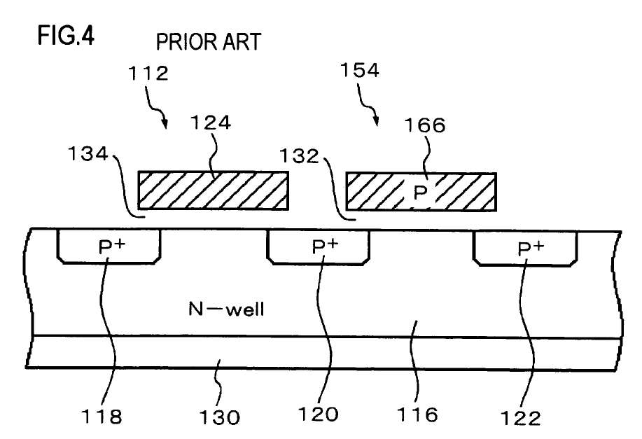

FIGS. 5A to 5E are process sectional views schematically illustrating a method of manufacturing a non-volatile memory according to the prior art.

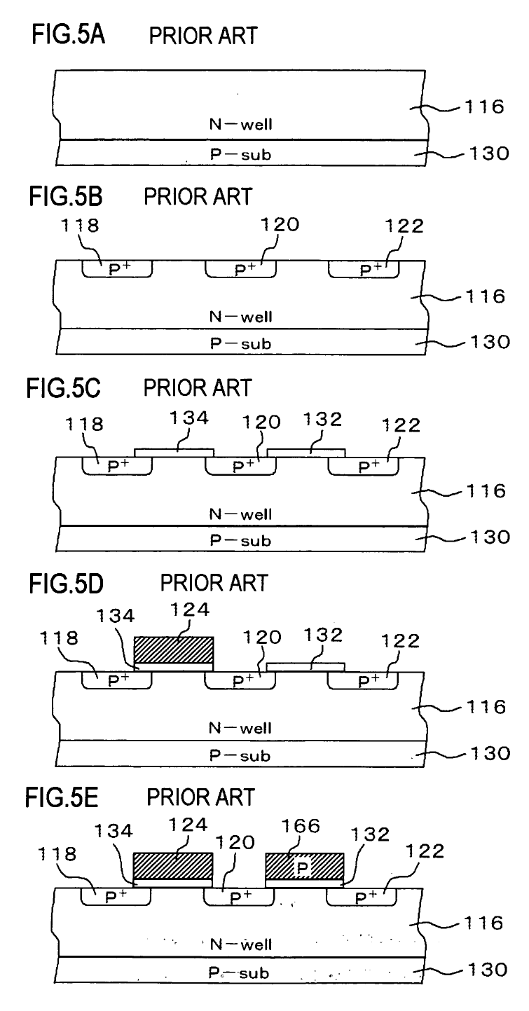

### PREFERRED MODES

### First Example

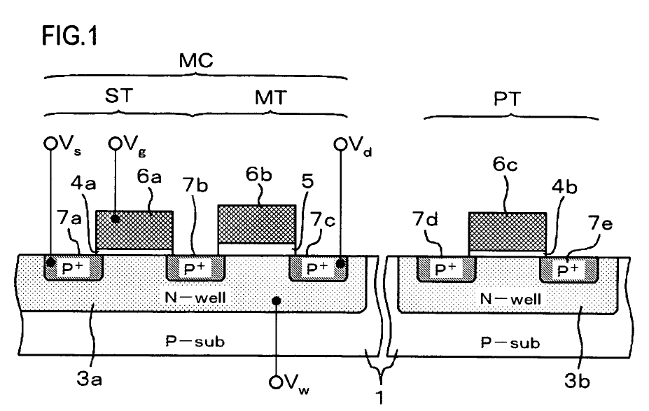

A non-volatile memory according to a first example of the present invention will now be described with reference to the drawings. FIG. 1 is a partial sectional view schematically illustrating the structure of a non-volatile memory according to a first example of the present invention.

The non-volatile memory is a single-layer-gate non-volatile memory. The non-volatile memory includes a plurality of memory cells MC, which form the memory portions, disposed in the form of an array on a substrate 1. A peripheral-circuit transistor PT that includes a logic circuit is disposed at the periphery of the memory cell array.

In the memory cell MC, a PMOS transistor relating to a select transistor ST is serially connected to a PMOS transistor relating to a memory transistor MT. The reason for using PMOS transistors is that the potential difference between the gate and substrate is greater than in the case of a NMOS transistor, the electron holding characteristic is better and the gate insulating film can be made thin. In the memory cell MC, an N-type well 3a in which a pentavalent element has been injected has been formed on the substrate 1, which comprises a P-type silicon substrate. A P-type diffusion region 7a, P-type diffusion region 7b and P-type diffusion region 7c in which a trivalent element has been injected have been formed on the N-type well 3a. A select gate 6a comprising polysilicon and a metal, etc., has been formed via a select-gate insulating film 4a, which comprises silicon oxide, etc., over a channel between the P-type diffusion region 7a and P-type diffusion region 7b. A floating gate 6b comprising polysilicon and a metal, etc., has been formed via a floating-gate insulating film 5, which comprises silicon oxide, etc., over a channel between the P-type diffusion region 7b and P-type diffusion region 7c. The film thickness of the select-gate insulating film 4a is equal to that of a peripheral-circuit gate insulating film 4b. The arrangement is such that the film thickness of the floating-gate insulating film 5 is greater than that of the peripheral-circuit gate insulating film 4b. The P-type diffusion region 7a is supplied with source voltage (Vₛ) via a source line (not shown), the select gate 6a is supplied with gate voltage (V_{g}) via a word line (not shown), the P-type diffusion region 7c is supplied with drain voltage (V_{d}) via a bit line (not shown), and the N-type well 3a is supplied with well voltage (V_{w}).

In the peripheral-circuit transistor PT, an N-type well 3b in which a pentavalent element has been injected has been formed on the P-type substrate 1. The N-type well 3b has an impurity concentration the same as that of the N-type well 3a. A P-type diffusion region 7d and a P-type diffusion region 7e in which a trivalent element has been injected have been formed on the N-type well 3b. The impurity concentrations of the P-type diffusion region 7d and P-type diffusion region 7e are the same as the impurity concentrations of the P-type diffusion region 7b and P-type diffusion region 7c. A peripheral-circuit gate 6c comprising polysilicon, a metal or the like, has been formed via a peripheral-circuit gate insulating film 4b, which comprises silicon oxide, etc., over a channel between the P-type diffusion region 7d and P-type diffusion region 7e. The arrangement is such that the film thickness of the peripheral-circuit gate insulating film 4b is equal to that of the select-gate insulating film 4a and less than that of the floating-gate insulating film 5.

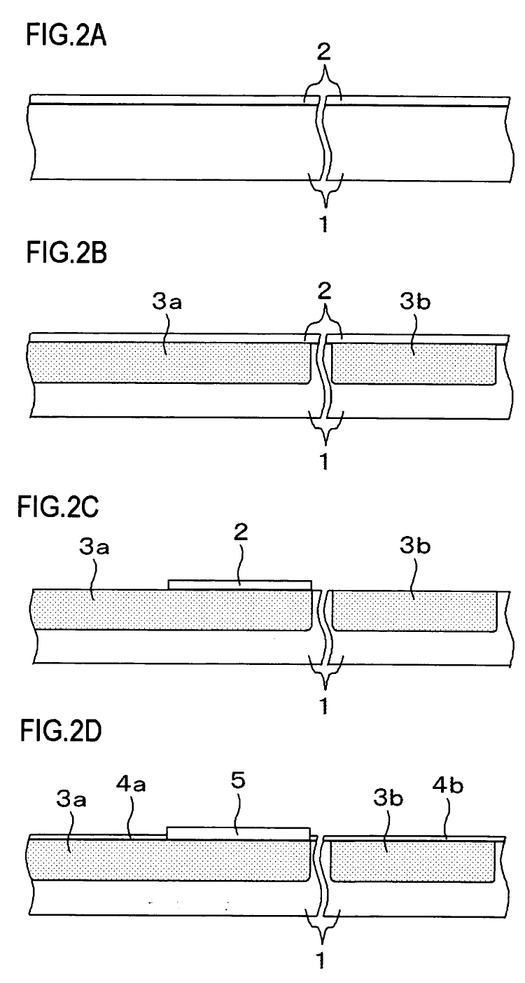

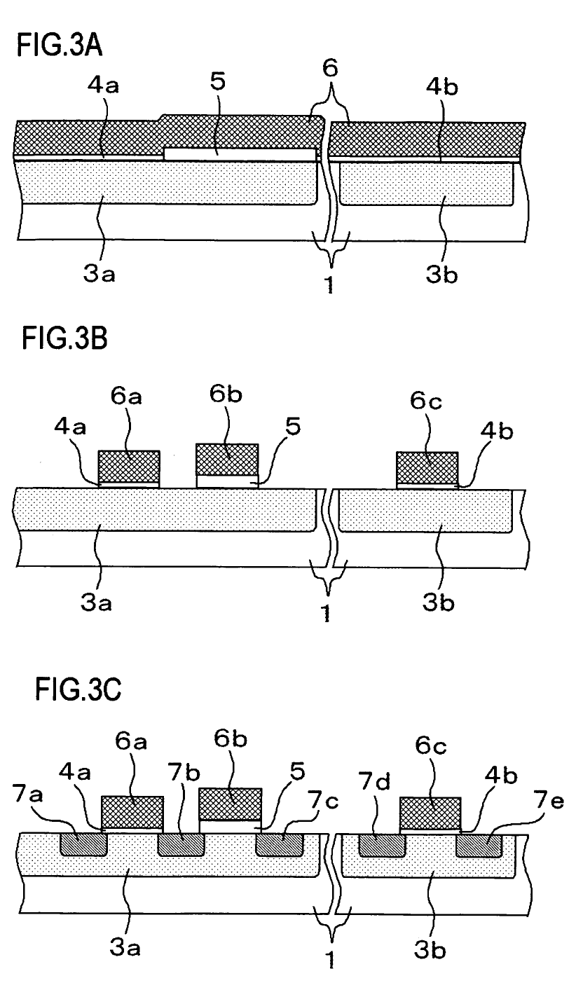

A method of manufacturing a non-volatile memory according to the first example will be described with reference to the drawings. FIGS. 2A to 2D and FIGS. 3A to 3C are process sectional views schematically illustrating a method of manufacturing a non-volatile memory according to the first example.

First, after a device isolation region (e.g., STI, etc., not shown) has been formed on the substrate 1 (P-type silicon substrate), a through-insulating film (sacrificial oxide film) 2 having a prescribed thickness (e.g., 10 nm) is formed on the substrate 1 by thermal oxidation (see FIG. 2A).

Next, N-type wells 3a, 3b are formed in a peripheral-circuit region and memory-cell region by injecting ions simultaneously into the peripheral-circuit region and memory-cell region of the substrate 1 (see FIG. 2B). It should be noted that the through-insulating film 2 remains ever after the N-type wells 3a, 3b have been formed. Further, the N-type wells 3a, 3b of the peripheral-circuit region and memory-cell region have identical impurity concentrations.

Next, the through-insulating film 2 is covered with a photo resist (not shown), a photo-resist mask is formed by exposing and developing areas other than a memory-transistor MT area, the through-insulating film 2 in areas other than the memory-transistor MT area is removed by, e.g., wet etching, and then the photo-resist mask is removed (see FIG. 2C). It should be noted that whereas the through-insulating film 2 is removed entirely in the case of the conventional MOS transistor process, it remains although only in the area of the memory transistor MT according to the present invention.

Next, the select-gate insulating film 4a and peripheral-circuit gate insulating film 4b having a prescribed thickness (e.g., 3.5 nm) are formed in the peripheral-circuit PT region and select transistor ST region by thermal oxidation (see FIG. 2D). Since the through-insulating film 2 formed at the preceding step is additionally oxidized in the memory-transistor region at this time, the floating-gate insulating film 5, which has a thickness on the order of, e.g., 11 nm, is formed, that is substantially thicker than that of the select-gate insulating film 4a and peripheral-circuit gate insulating film 4b. By thus oxidizing the through-insulating film 2 to obtain the floating-gate insulating film 5, impurities and defects in the through-insulating film 2 ascribable to ion injection are mitigated so that the effects of these on the reliability of the floating-gate insulating film 5 are negligible. Further, since the floating-gate insulating film 5 has a thickness that is at least double the film thickness of the select-gate insulating film 4a and peripheral-circuit gate insulating film 4b, influence on the reliability of the floating-gate insulating film 5 is negligible. Furthermore, since the select-gate insulating film 4a has a thickness that is at most one-half the film thickness of the floating-gate insulating film 5, the difference between ON/OFF of the cell current in the memory cell can be made sufficiently large and influence on the reliability of the floating-gate insulating film 5 is negligible.

Next, a gate layer 6 comprising polysilicon or the like, is formed over the entire surface that includes the select-gate insulating film 4a, peripheral-circuit gate insulating film 4b and floating-gate insulating film 5 (see FIG. 3A).

Next, the gate layer 6 is covered with a photo resist (not shown), a photo-resist mask is formed by exposing and developing areas other than those of the select gate 6a, floating gate 6b and peripheral-circuit gate 6c, the select-gate insulating film 4a, peripheral-circuit gate insulating film 4b and floating-gate insulating film 5 in the areas other than those of the select gate 6a, floating gate 6b and peripheral-circuit gate 6c are removed by dry etching, and then the photo-resist mask is removed (see FIG. 3B). It should be noted that the film thicknesses of the select gate 6a, floating gate 6b and peripheral-circuit gate 6c are equal.

Next, by injecting ions simultaneously into the N-type wells 3a, 3b on both sides of the select gate 6a, floating gate 6b and peripheral-circuit gate 6c, the P-type diffusion regions 7a, 7b, 7c, 7d and 7e are formed (see FIG. 3C). This is followed by forming interlayer insulating films and wiring, etc.

Next, an example of operation of the non-volatile memory according to the first example of the invention will be described.

Assume that in a case where logical “1” is written in the memory cell MC, the gate (select gate) voltage (V_{g}) of the word line and the drain (3rd diffusion region) voltage (V_{d}) of the bit line are made 0V and the source (1st diffusion region) voltage (Vₛ) of the source line and the (N-) well voltage (V_{w}) are made 6V. Under these conditions, the select transistor ST is rendered conductive, thermal electrons are injected into the floating gate 6b of the memory transistor MT from the P-type diffusion region 7a through the P-type diffusion region 7b, and the state in which “1” has been written to the device is attained.

Assume that in a case where the memory cell MC is read, the gate voltage (V_{g}) of the word line is made 0V, the drain voltage (V_{d}) of the bit line is made 1V, the source voltage (Vₛ) of the source line is made 2V and the well voltage (V_{w}) is made 2V. If logical “1” has already been written in the memory cell MC, then electrical charge will have already accumulated in the floating gate 6b and the memory cell MC will be rendered conductive. On the other hand, if logical “0” has been written, i.e., if logical “1” has not been written, then the floating gate 6b will not be storing any charge and the memory cell MC will be rendered non-conductive.

With regard to erasure of the memory cell MC, since writing is performed only one time, erasure of the memory cell MC is not contemplated. However, if erasure is necessary in actual practice, this can be achieved by irradiation with UV.

In accordance with the first example, the thick through-insulating film 2 formed before the ion injection for the formation of the N-type wells 3a, 3b is used for the floating-gate insulating film 5 in the memory transistor MT. As a result, the thick floating-gate insulating film 5 for the memory transistor MT can be formed without adding on a process step for forming a thick gate oxide film.

Further, since the N-type well 3a of the memory cell MC is formed at the same process step as that for the N-type well 3b of the region of peripheral-circuit transistor PT, the N-type well 3a of the memory cell MC can be formed without adding on a process step.

Furthermore, since the select-gate insulating film 4a of the select transistor ST is thin, it is possible to increase the ON current in comparison with the case where the select-gate oxide film 134 is thick, as in the example of the prior art described above. The operating speed of the memory is raised as a result.

As many apparently widely different modes of the present invention can be made without departing from the spirit and scope thereof, it is to be understood that the invention is not limited to the specific examples thereof except as defined in the appended claims.

What is claimed is:

1. A non-volatile memory comprising:
in a memory cell, first, second and third diffusion regions formed in a well;
a select gate formed via a select-gate insulating film over a channel between said first and second diffusion regions; and
a floating gate formed via a floating-gate insulating film over a channel between said second and third diffusion regions;
wherein said floating-gate insulating film has a film thickness greater than that of said select-gate insulating film.

2. The memory according to claim 1, further comprising:
in a peripheral circuit disposed peripheral to said memory cell, fourth and fifth diffusion regions formed in a well; and
a peripheral-circuit gate formed via a peripheral-circuit gate insulating film over a channel between said fourth and fifth diffusion regions; wherein
the wells of said memory cell and said peripheral circuit have identical impurity concentrations.

3. The memory according to claim 1, wherein said select-gate insulating film has a film thickness equal to that of said peripheral-circuit gate insulating film.

4. The memory according to claim 1, wherein the well of said memory cell is an N-type well; and
said first, second and third diffusion regions are P-type diffusion regions.

5. The memory according to claim 2, wherein the well of said memory cell is an N-type well; and
said first, second and third diffusion regions are P-type diffusion regions.

6. The memory according to claim 3, wherein the well of said memory cell is an N-type well; and
said first, second and third diffusion regions are P-type diffusion regions.

7. The memory according to claim 2, wherein the well of said peripheral circuit is an N-type well; and
said fourth and fifth diffusion regions are P-type diffusion regions.

8. The memory according to claim 3, wherein the well of said peripheral circuit is an N-type well; and
said fourth and fifth diffusion regions are P-type diffusion regions.

9. The memory according to claim 4, wherein the well of said peripheral circuit is an N-type well; and
said fourth and fifth diffusion regions are P-type diffusion regions.

10. A method of manufacturing a non-volatile memory comprising:
forming a through-insulating film, which is for well formation, on a substrate;
forming wells in the substrate by ion injection;
removing the through-insulating film at least in areas other than an area in which a memory transistor will be formed in the memory cell; and
forming an insulating film, which is thinner than the through-insulating film, at least on the well that is in an area in which a select transistor will be formed in the memory cell.

11. The method according to claim 10, wherein when the wells are formed, the wells of the memory cell and peripheral circuit are formed simultaneously.

12. The method according to claim 11, wherein when the thinner insulating film is formed, an insulating film thinner than the through-insulating film is formed also on the well of the peripheral circuit.

13. A method of operating a non-volatile memory comprising:
providing a non-volatile memory comprising:
in a memory cell, first, second and third diffusion regions formed in a well;
a select gate formed via a select-gate insulating film over a channel between said first and second diffusion regions; and
a floating gate formed via a floating-gate insulating film over a channel between said second and third diffusion regions;
wherein said floating-gate insulating film has a film thickness greater than that of said select-gate insulating film; and
applying a first volatile across from the first diffusion region and the well to the select gate, the third diffusion region being held at a second voltage that is same as the select gate;
thereby performing writing in the memory cell.

14. The method according to claim 13, wherein reading is performed by applying:
a third voltage lower than the first voltage to the well and the first diffusion region;
a fourth voltage lower than the third voltage to the third diffusion region; and
a fifth voltage lower than the fourth voltage to the select gate.
